(19) United States
(12) Patent Application Publication
(10) Pub. No.: US 2007/0023142 A1
(43) Pub. Date: Feb. 1, 2007

(54) AIRFOIL REFURBISHMENT METHOD

(76) Inventors: John Robert LaGraff, Niskayuna, NY (US); James Anthony Ruud, Delmar, NY (US); Dong-Sil Park, Niskayuna, NY (US); Leo Spitz MacDonald, Schenectady, NY (US); John Joseph Bottoms, Huntersville, NC (US); Claudino Koakowski, Sugarland, TX (US)

Correspondence Address: GENERAL ELECTRIC COMPANY;GLOBAL RESEARCH, PATENT DOCKET RM. BLDG. K1-4A59, NISKAYUNA, NY, 12309, US

(21) Appl. No.: 11/528,946

(22) Filed: Sep. 28, 2006

Related U.S. Application Data
(62) Division of application No. 10/325,475, filed on Dec. 19, 2002.

(51) Int. Cl. C23F 1/00; C23C 16/00

(52) U.S. Cl. 156/345.31; 118/719

(57) ABSTRACT

An airfoil refurbishment system is disclosed. The airfoil refurbishment system includes an environmentally safe stripper system and an aluminiding system. The environmentally safe stripper system includes a transportable environmentally safe compound that is capable of partially removing an aluminide coating from an airfoil. The aluminiding system is capable of restoring the aluminide coating to the airfoil.

### BACKGROUND OF INVENTION

The present invention generally relates to an airfoil refurbishment system and, more particularly, to a system including an environmentally safe stripper system that is capable of partially removing an aluminide coating from an airfoil.

Airfoils are used in aircraft engine turbines and power generation turbines to translate combustion into rotational motion. In an aircraft engine turbine, the rotational motion is used to spin fans in the compressor to sustain rotation and fans that create thrust, which in conjunction with wings, lifts an aircraft for flight. In a power generation turbine, that rotational motion also is used to spin fans in the compressor to sustain rotation and, rather than fans, perform mechanical work such as the rotation of a generator to produce electricity. For either of these turbines, increasing the operating temperature of the turbine section can increase operating efficiency. However, materials from which an airfoil is made may limit the operating temperature.

A technique that has been used to allow for increased operating temperature is the use of one or more refractory coatings on a base metal from which an airfoil is formed. Examples of such coatings include aluminide and thermal barrier coatings. In time, however, a coating degrades. Options for addressing coating degradation include replacing an airfoil having a compromised coating with a new airfoil having a new coating or refurbishment of the airfoil having the compromised coating.

The refurbishment of a compromised coating is a technique currently used in the art. There are several disadvantages with current refurbishment. One major disadvantage is that no integrated system exists for refurbishment. For example, aircraft engine turbines and power generation turbines are typically overhauled at or near their location of employment. For an aircraft engine turbine that location may anywhere throughout the world such as an airport or aircraft maintenance facility. For a power generation turbine that location is usually the location of the turbine, again, anywhere in the world. As a general rule, there is a dearth of equipment at the turbine overhaul site for performing any of the number of steps of airfoil refurbishment, let alone an integrated system for all of the steps of refurbishment. Thus, after airfoils are removed from their respective turbine, the airfoils are sent to a first remote location to remove the compromised coating. The coating removal is typically a complete removal of the compromised coating to the base metal. Once the compromised coating is removed, the airfoils may be sent to a second remote location for the recoating.

Also, the time for the refurbishment of an airfoil prior to replacement into the turbine includes the time for transporting from the overhaul location to the first remote location, from the first remote location to the second remote location, and from the second remote location back to the location of the turbine. Sometimes the time may be greater including the time for a roundtrip from the turbine location to the first remote location and the time for a roundtrip from the turbine location to the second remote location. As a turbine often is located in a first country, the first remote location is in a second country, and the second remote location is in a third country, the time for transporting airfoils can become frustrated by the time needed to clear customs of both the turbine location country and the remote location countries.

Another disadvantage of current refurbishment techniques for airfoils is the complete removal of the coating (i.e., the thermally grown oxide layer, alumide layer and diffusion layer). As aluminide coatings, refurbished coatings are made by first providing aluminum to the base metal from which an airfoil is made. At an elevated temperature, this aluminum diffuses into the base metal as at least one component of the base metal counter diffuses into the aluminum to create an aluminide layer outside of the base metal. At the same time, a diffusion layer is formed underneath the aluminide layer. The diffusion layer occupies a portion of the original base metal. Upon heating in an oxidizing environment, a thermally grown oxide layer grows on the aluminide layer.

During refurbishment, the thermally grown oxide layer, alumide layer and diffusion layer are removed from the airfoil. The removal of the thermally grown oxide layer and alumide layer presents the airfoil at substantially its original dimensions (i.e., the airfoil as made of just base metal and before an coating). However, with the removal of the diffusion layer, dimensions less than the original dimensions result since a portion of the original airfoil is removed. Stated differently, the removal of the diffusion layer results in a decrease in the size of the airfoil because that portion of the base metal that was converted to the diffusion layer is removed. Additionally, current refurbishment systems include environmentally hazardous operations, particularly, the coating removal operation.

In some applications, airfoils have thin walls. The removal of the diffusion layer can thus, substantially decrease the life of an airfoil. It would be desirable to have a system for refurbishment of an airfoil that would reduce the amount of time that the airfoil spends being transported from the turbine location to the first remote location to remove the compromised coating, then to the second remote location to recoat the airfoil and, finally back to the turbine location. Such a system for refurbishment of an airfoil would be integral, thereby allowing local refurbishment. Also, it would be desirable to have a system for refurbishment of an airfoil that has the ability to partially remove a compromised coating, thereby not substantially effecting the dimensions of the airfoil as defined by the original dimensions of the base metal used to make the airfoil.

Thus, there remains a need for a new and improved airfoil refurbishment system which includes an environmentally safe stripper system that is capable of partially removing an aluminide coating from an airfoil.

### SUMMARY OF INVENTION

The present invention is directed to an airfoil refurbishment system that includes an environmentally safe stripper system and an aluminiding system. The environmentally safe stripper system includes a transportable environmentally safe compound that is capable of partially removing an aluminide coating from an airfoil. The aluminiding system is capable of restoring the aluminide coating to the airfoil.

The aluminiding system may be a vapor phase based system such as, for example, one of a vapor-phase aluminizing system and a pack aluminizing system. Alternately, the aluminiding system may include a precursor applicator such as, for example, one of a slurry applicator and a foam applicator, in which the aluminum is provided to the substrate in the form of solid particles.

The aluminiding system may further including a heat treatment unit. The heat treatment unit may include a atmosphere controller that regulates the atmosphere in the heat treatment unit to be, for example, any one of an inert atmosphere, a reducing atmosphere, and a vacuous atmosphere as appropriate for replacing the alumide layer on an airfoil.

The transportable environmentally safe compound capable of partially removing an aluminide coating from an airfoil may be any one of phosphoric acid acetic acid and citric acid. Preferably, the transportable environmentally safe compound is phosphoric acid.

The environmentally safe stripper system may further include an oxide descaler such as, for example, any one of a mechanically based and chemically based oxide descaler. An example of the mechanically based oxide descaler is a grit blaster and an example of the chemically based oxide descaler is a citric acid based oxide descaler such as that disclosed in US 2002/0103093 A1 and EP1213370 entitled “Method and Composition for Cleaning a Turbine Engine Component,” the disclosure of which is herein incorporated by reference in it entirety.

The environmentally safe stripper system may further including a mask applicator. The mask applicator may be one of an automated applicator or a manual applicator. The manual applicator may be a person applying a mask as appropriate.

In a preferred embodiment, the environmentally safe stripper system is an aluminide stripper. Such a stripper may be a chemical bath that may further includes, for example, any one of a fume hood, a support basket, an agitator, a rinse bath, a desmutter and any combination thereof.

Accordingly, one aspect of the present invention is to provide an airfoil refurbishment system that includes an environmentally safe stripper system. The environmentally safe stripper system is capable of partially removing an aluminide coating from an airfoil.

Another aspect of the present invention is to provide an airfoil refurbishment system that includes an environmentally safe stripper system. The environmentally safe stripper system includes a transportable environmentally safe compound that is capable of partially removing an aluminide coating from an airfoil.

Still another aspect of the present invention is to provide an airfoil refurbishment system that includes an environmentally safe stripper system and an aluminiding system. The environmentally safe stripper system includes a transportable environmentally safe compound that is capable of partially removing an aluminide coating from an airfoil. The aluminiding system is capable of restoring the aluminide coating to the airfoil.

These and other aspects of the present invention will become apparent to those skilled in the art after a reading of the following description of the preferred embodiment when considered with the drawings.

### BRIEF DESCRIPTION OF DRAWINGS

FIG. 1 is a system for the refurbishment of an airfoil according to an embodiment of the present invention;

FIG. 2 is a detailed schematic view of a sub-system for stripping an airfoil as may be used in the airfoil refurbishment system of FIG. 1;

FIG. 3A is a Table containing a summary of transportability characteristics and health characteristics for a variety of acids;

FIG. 3B is a Table containing a rating of transportability characteristics and health characteristics for the variety of acids of the Table of FIG. 3A;

FIG. 3C is a topographic plot of the reactivity of the acids of Tables of FIGS. 3A & 3B as a function of transportability characteristics and health characteristics;

FIG. 4A is a detailed schematic view of an embodiment of a sub-system for aluminiding an airfoil as may be used in the airfoil refurbishment system of FIG. 1;

FIG. 4B is a detailed schematic view of an alternative embodiment of a sub-system for aluminiding an airfoil as may be used in the airfoil refurbishment of FIG. 1;

FIG. 5 is an airfoil according to an embodiment of the present invention;

FIG. 6A is a schematic view of an as-received base alloy including an aluminide layer, a diffusion zone with a thermally grown oxide layer that formed on the aluminide layer after being in a turbine during operation;

FIG. 6B is a schematic view of the base alloy after the thermally grown oxide layer, the aluminide layer, and the diffusion zone have been chemically removed showing that some base metal and areas having a eutectic composition have been attacked;

FIG. 6C is a schematic view of the re-aluminided base alloy;

FIG. 7A is a schematic view of an as-received base alloy including a diffusion zone and an aluminide layer with a thermally grown oxide layer that formed on the aluminide layer after being in a turbine during operation;

FIG. 7B is a schematic view of the base alloy after only the thermally grown oxide layer has been chemically removed showing that the base metal and areas having a eutectic composition are not attacked;

FIG. 7C is a schematic view of the re-aluminided aluminide layer on the base alloy;

FIG. 8A is a schematic view of an as-received base alloy including an aluminide layer, a diffusion zone with a thermally grown oxide layer that formed on the aluminide layer after being in a turbine during operation;

FIG. 8B is a schematic view of the base alloy after the thermally grown oxide layer and a portion of the aluminide layer have been chemically removed showing that the base metal and areas having a eutectic composition are not attacked;

FIG. 8C is a schematic view of the re-aluminided partially removed aluminide layer on the base alloy;

FIG. 9A is a scanning electron micrograph (SEM) of a cross-section of an as-received aluminided airfoil where the black arrows indicate the diffusion zone;

FIG. 9B is a scanning electron micrograph (SEM) of a cross-section of as-received aluminided airfoil after partial stripping with phosphoric acid where the black arrows indicate the diffusion zone;

FIG. 10A is a scanning electron micrograph (SEM) of a cross-section of an after-service aluminided (the thickness is about 2-3 mils) airfoil pressure surface after partial stripping with phosphoric acid;

FIG. 10B is a scanning electron micrograph (SEM) of a cross-section of an after-service aluminided (the thickness is about 2-3 mils) airfoil pressure surface after partial stripping with phosphoric acid and re-aluminiding after a vapor hone;

FIG. 10C is a scanning electron micrograph (SEM) of a cross-section of an after-service aluminided (the thickness is about 2-3 mils) airfoil pressure surface after partial stripping with phosphoric acid and re-aluminiding without a vapor hone;

FIG. 11A is a scanning electron micrograph (SEM) of a cross-section of an after-service aluminided (the thickness is about 2-3 mils) airfoil cooling hole surface after partial stripping with phosphoric acid;

FIG. 11B is a scanning electron micrograph (SEM) of a cross-section of an after-service aluminided (the thickness is about 1 mil) airfoil cooling hole surface after partial stripping with phosphoric acid and re-aluminiding after a vapor hone; and

FIG. 11C is a scanning electron micrograph (SEM) of a cross-section of an after-service aluminided (the thickness is about 2-3 mils) airfoil cooling hole surface after partial stripping with phosphoric acid and re-aluminiding without a vapor hone.

### DETAILED DESCRIPTION

In the following description, like reference characters designate like or corresponding parts throughout the several views. Also in the following description, it is to be understood that such terms as “forward,” “rearward,” “left,” “right,” “upwardly,” “downwardly,” and the like are words of convenience and are not to be construed as limiting terms.

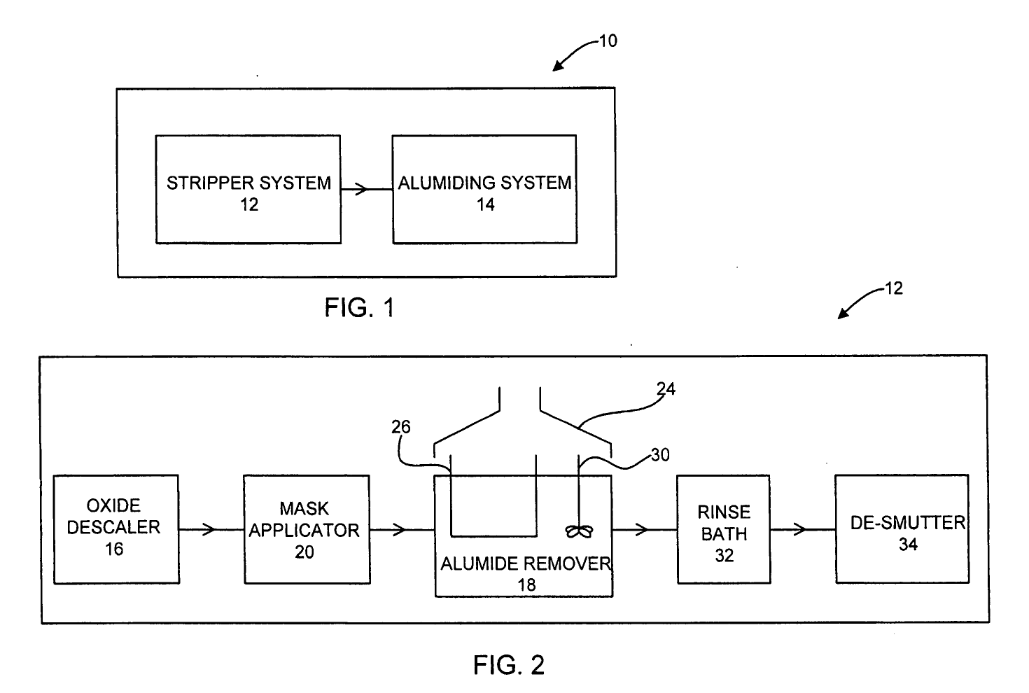

Referring now to the drawings in general and FIG. 1 in particular, it will be understood that the illustrations are for the purpose of describing a preferred embodiment of the invention and are not intended to limit the invention thereto. As best seen in FIG. 1, an airfoil refurbishment system, generally designated 10, is shown constructed according to the present invention. The airfoil refurbishment system 10 includes two major sub-assemblies, a stripper system 12 and an aluminiding system 14. As such, an airfoil refurbishment system 10 may be contained within a single building or a single facility.

One advantage of such an airfoil refurbishment system 10 is that it may be based on low capital investment. Another advantage of such an airfoil refurbishment system 10 is that can be placed within a turbine repair facility or proximate to a turbine repair facility. Yet another advantage of this system is that the stripper system that may be use to remove the thermally grown oxide layer and aluminide layer, in any amount from partially to substantially completely, from an airfoil may be approximate to the aluminiding system that is used for recoating the airfoil.

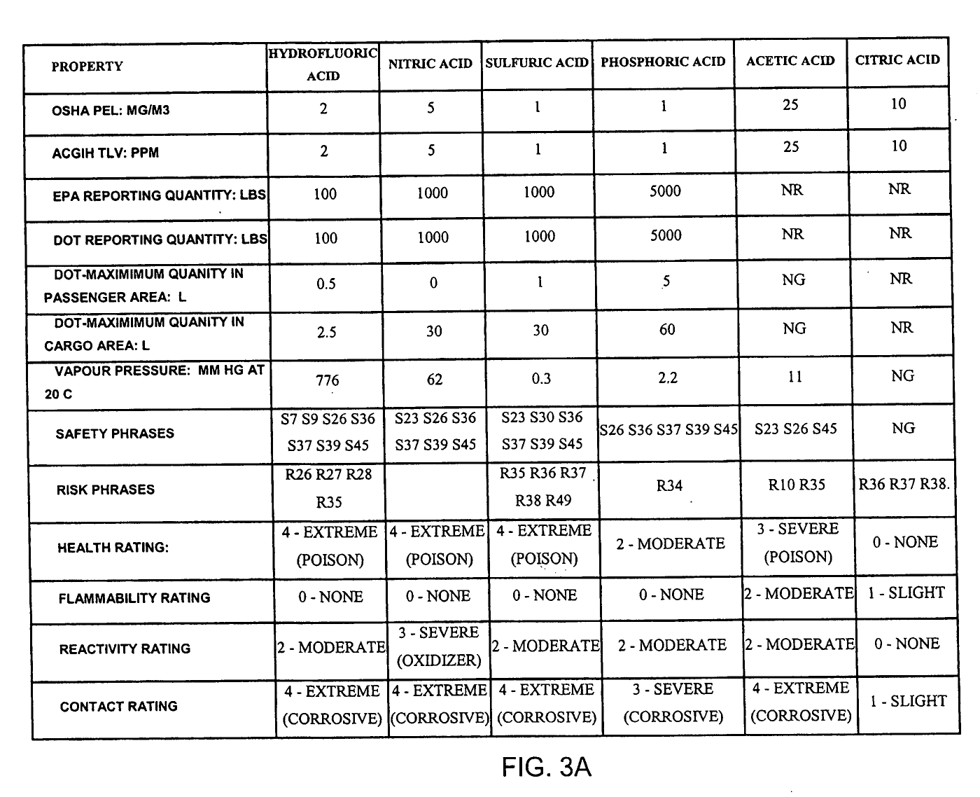

More details concerning the stripper system may be seen in FIG. 2. Here the stripper system 12 includes a variety of units, for example, an oxide descaler 16, a mask applicator 20, an aluminide remover 18, a rinse bath 32, and a desmutter 34. Some of these operations may be independently known within the art however, not in a combined manner as described in the present application.

The oxide descaler 16 may be used to remove a variety of types of oxide scales. A main purpose of the oxide descaler 16 is the removal of thermally grown oxide layers. However, it is contemplated that the oxide descaler 16 may also be used to remove thermal barrier coatings such as the high ceramic and insulating coatings used on aircraft engine airfoils. The oxide descaler 16 may be either mechanically based or chemically based. In the case of a mechanically based operation, the oxide descaler 16 might be a grit blaster. For a oxide descaler 16 that is chemically based, the chemical may be a composition ranging from acidic to basic that has the ability of removing the oxide layer that is formed on the aluminide layer during operation of the turbine.

The stripper 12 also may include a mask applicator 20. The mask applicator 20 may be used to selectively protect areas of a coating on an airfoil or exposed portion of the base metal of the airfoil prior to a removal of the aluminide layer. The mask applicator 20 may be a human whose responsibility is to apply the mask to an airfoil. Alternatively, mask applicator 20 may be a manually operated device. As another alternative, the mask applicator 20 may be an automated device that identifies locations to be masked on an airfoil that is being refurbished and then masks the locations in an appropriate manner.

The stripper 12 includes an aluminide remover 18 such as, for example, a chemical bath containing a transportable environmentally safe compound capable of removing an aluminide coating from an airfoil. In particular, the nature of the transportable environmentally safe compound and its formulation to make the chemical bath contributes to the environmental safety of the stripper 12.

Among factors to be considered in selecting a transportable environmentally safe compound for a chemical bath in constructing the environmentally safe stripper 12 include the nature of exposure limits, health effects of overexposure, safe handling procedures, emergency procedures, personal protective equipment and engineering controls. Among exposure limits are, for example, the OSHA PEL (OSHA's “Permissible Exposure Limit”—The maximum amount of the chemical that an employee can be exposed to without danger over a typical 8 hour day) and the ACGIH TLV (“Threshold Limit Value”—Another safe exposure limit set by the American Conference of Governmental Industrial Hygienists). Among the nature of safe handling procedures, emergency procedures, personal protective equipment and engineering controls, properties such as evaporation Rate (Another measurement of how quickly a liquid or solid turns into a gas, where the higher the number, the faster the rate), the solubility in water (how much of the chemical will dissolve in water), and lower and upper explosive limits (LEL and UEL, the minimum and maximum percent vapor in the air that could explode if ignited).

Source for such information include national and international health and safety standards. For example, International Chemical Safety Cards (ICSC) might be used to quantify the environmental safety of the stripper 12. These ICSC are available from the International Occupational Safety and Health Information Centre (CIS) there is an ongoing co-operation of National and Collaborating Centres all over the world. Examples of just some of the co-operating National Centres include National Occupational Health and Safety Commission (NOHSC); Canadian Centre for Occupational Health and Safety (CCOHS); National Center for Safety Science and Technology Research in China; Institut national de recherche et de sécurité (INRS) in France; Bundesanstalt für Arbeitsschutz und Arbeitsmedizin (BAuA) in Germany; Japan Industrial Safety and Health Association (JISHA); Vserossijskij centr ohrany i Proizvoditel'nosti truda (All-Russia Labour Protection and Productivity Centre); Health and Safety Executive in the United Kingdom; and National Institute for Occupational Safety and Health in the United States.

Examples of a suitable transportable environmentally safe compounds include any one of phosphoric acid, acetic acid and citric acid. Preferably, the transportable environmentally safe compound is phosphoric acid.

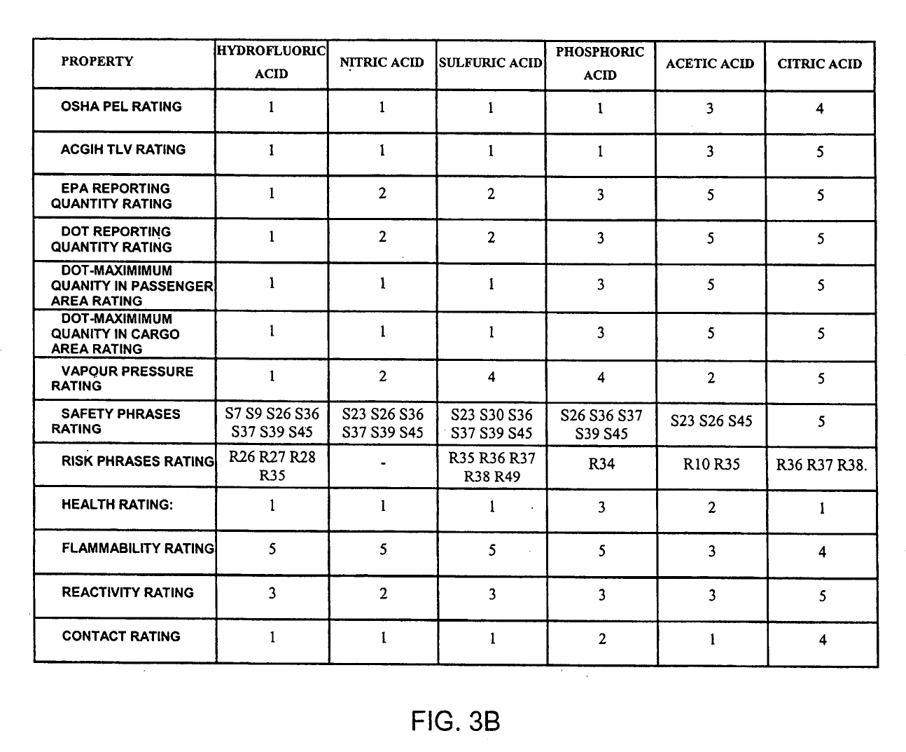

FIG. 3A is a Table containing a summary of some characteristics for hydrofluoric acid, nitric acid, sulfuric acid, phosphoric acid, acetic acid and citric acid. The characteristics relate to the transportability characteristics and environment and health characteristics. Among the transportability characteristics are the Department of Transportation (DOT) reporting quantity, DOT maximum quantity in passenger area, and DOT maximum quantity in cargo area. Among the environment and health characteristics are the Occupational Safety & Health Administration (OSHA) permissible exposure limit (PEL), the American Conference of Governmental Industrial Hygienists (ACGIH) threshold limit values (TLV), and the US Environmental Protection Agency (EPA) reporting quantity. A property influencing the above to categories is the vapour pressure of the acid. For some of the environmentally safer acids that the subject of the present invention the designation NR and NG are provided in the Table of FIG. 3A. Here NR means not regulated and NG means not given.

The Table of FIG. 3A also refers to safety and risk phrases that have been developed Under European Community (EC) legislation to provide direction to users of materials. These phrases are also extensively used elsewhere in the world. Safety phrase codes relating to the acids of FIG. 3A have the following meanings:

S7 Keep container tightly closed;

S9 Keep container in a well-ventilated place;

S23 Do not breathe vapour;

S26 In case of contact with eyes, rinse immediately with plenty of water and seek medical advice;

S30 Never add water to this product;

S36 Wear suitable protective clothing;

S37 Wear suitable gloves;

S39 Wear eye/face protection;

S45 In case of accident or if you feel unwell, seek medical advice immediately (show the label whenever possible); and

S46 If swallowed, seek medical advice immediately and show this container or label.

Risk phrase codes relating to the acids of FIG. 3A have the following meanings:

R10 Flammable;

R26 Very toxic by inhalation;

R27 Very toxic in contact with skin;

R28 Very toxic if swallowed;

R34 Causes burns;

R35 Causes severe burns;

R36 Irritating to eyes;

R37 Irritating to respiratory system;

R38 Irritating to skin; and

R49 May cause cancer by inhalation.

Finally, the Table of FIG. 3A also refers to “SAF-T-DATA™ Ratings” that have been developed by J.T. Baker, a division of Mallinckrodt Baker, Inc., to provide direction to users of materials. The SAF-T-DATA™ Ratings relating to the acids of FIG. 3A have the following meanings:

0—None (No scientific data in standard references suggest the substance is dangerous)

1—Slight

2—Moderate

3—Severe

4—Extreme

In each of the four categories:

Health—The danger or toxicity the substance presents if inhaled, ingested, or absorbed, including potential effect on human/animal reproductive process,

Flammability—The tendency of the substance to burn.

Reactivity—The potential of the substance to explode or react violently with air, water or other substance.

Contact—The danger the substance presents when exposed to skins, eyes, and mucous membranes.

In FIG. 3B is a Table the rates the data of the Table of FIG. 3A on a scale ranging from 1 to 5. The rating of 1 is the lowest rating meaning that with respect to that characteristic that acid is undesirable. A rating of 3 is the intermediate rating meaning that with respect to that characteristic that acid is acceptable. A rating of 5 is the highest rating meaning that with respect to that characteristic that acid is exceptional. A rating of 2 fall between 1 and 3 while rating of 4 fall between 3 and 5.

Taking the ratings from the Table of FIG. 3B and taking into account the effectiveness of the acid in refurbishing airfoils according to the present invention, on get FIG. 3C. This figure is a topographic plot of the reactivity of the acids of Tables of FIGS. 3A & 3B as a function of transportability characteristics and health characteristics. Here again the effectiveness of the acids is rated from 1 to 5 where again 1 is poor, 3 is satisfactory, and 5 is the best. Even though hydrofluoric acid and nitric acid are exceptional for removing coatings, their health and transportability ratings are poor. Sulfuric acid also suffers from poor health and transportability ratings while having almost exceptional coating removal characteristics. Phosphoric acid and acetic acid, while having acceptable coating removal characteristics exhibit exception transportability characteristics and acceptable health characteristics. Citric acid, while having exceptional transportability and health characteristics, exhibits poor coating removal characteristics. Thus according to the present invention it can be said that phosphoric acid and acetic acid are transportable environmentally safe compounds capable of removing an aluminide coating.

The chemical bath containing a transportable environmentally safe compound capable of removing an aluminide coating from an airfoil of the present invention may also include various additives that serve a variety of functions, such as catalytic regulators. Non-limiting examples of these additives are inhibitors, dispersants, surfactants, chelating agents, wetting agents, deflocculants, stabilizers, anti-settling agents, and anti-foam agents. Those of ordinary skill in the art are familiar with specific types of such additives, and with effective levels of use. Examples of inhibitors might be used are described in the Handbook of Corrosion Engineering, P. Roberge, McGraw-Hill, NY 1999, e.g., pp. 833-862, which is incorporated herein by reference. Many inhibitors are available commercially, e.g., the various Rhodine™ products available from Henkel Surface Technologies, Inc., Madison Heights, Mich.

The chemical bath may include for example, a fume hood 24, a support basket 26, a heating element, an ultrasonic agitator and/or a physical agitator 30, including impellers and spargers. In this case, this chemical bath is an environmentally safe system. The bath has properties such that it is safe for operators having little or no background in a chemical processes to operate, as well as being safe for such operators.

The stripper system 12 may also include a rinse bath 32, and a de-smutter 34, each of which aid in the cleaning of an airfoil after it has been subjected to the aluminide remover.

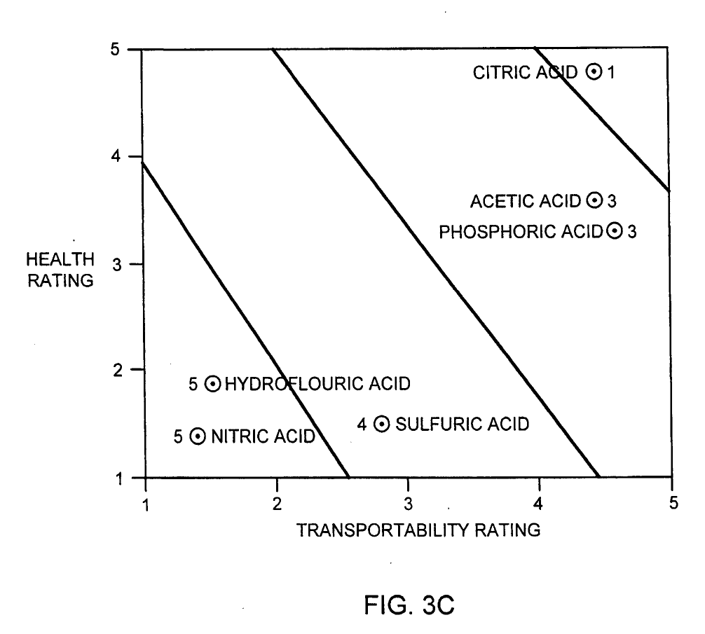

Turning now to FIGS. 4A and 4B. They are depicted schematics views of the aluminiding system 14. Applicants contemplate that any of a variety of aluminiding systems might be used. Including for example, a vapor phase based system or a system that includes a precursor applicator 36 a bake out unit, a heat treat unit 40 and a post-clean unit, as depicted in FIG. 4B. Basically the aluminiding system operates to apply a precursor material to the surface of the stripped airfoil to provide a means for the refurbishment of the aluminide coating. An example of such an aluminiding system is described in U.S. Pat. No. 6,299,935 entitled “Method For Forming A Coating By Use Of An Activated Foam Technique” issued in the names of Park et al., the disclosure of which is herein incorporated by reference in it entirety.

In the case of a vapor phase system as depicted in FIG. 4A, a providing of a precursor to the surface of the airfoil and formation of the aluminide coating may occur within the same unit. Examples of such systems include pack cementation systems and vapor phase systems where aluminum is provided either from a vapor species to the surface of the airfoil, at an elevated temperature, and as it is provided the aluminum defuses into and the base metal defuses out of the coating to form the aluminide. J.T. Baker, a division of Mallinckrodt Baker, Inc., is a supplier of aqueous stripper systems, which are example of systems usable in the present invention.

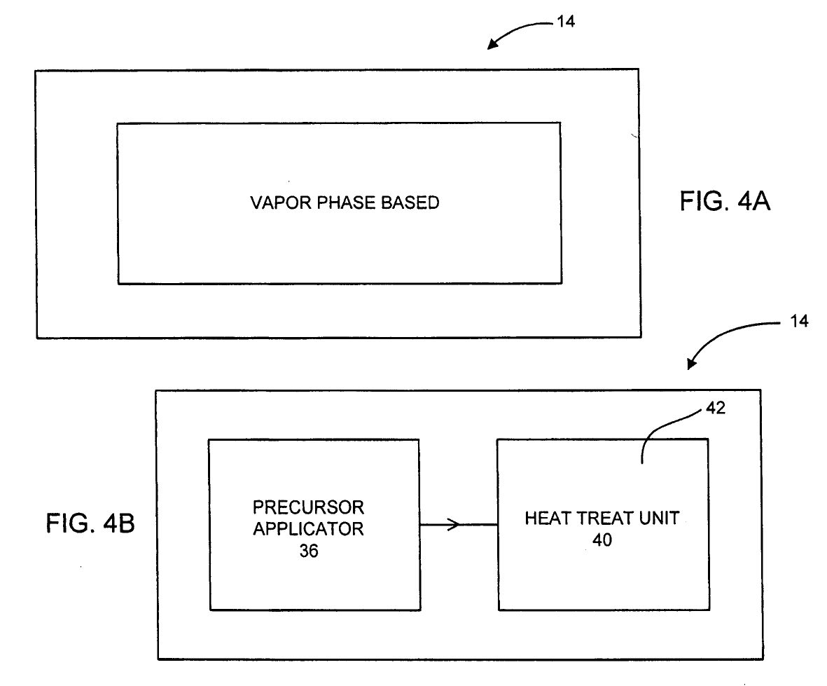

In FIG. 5, a gas turbine engine high pressure turbine blade 110 is shown from the airfoil concave side. The blade 110 includes a base 112 and an airfoil 114 that may include thereon a thermally grown oxide (TGO) layer and/or protective thermal barrier coating (TBC) system. Often, blade 110 is a superalloy. Such materials are known for high-temperature performance, in terms of tensile strength, creep resistance, oxidation resistance, and corrosion resistance, for example. The superalloy is typically nickel-, cobalt-, or iron-based, although nickel- and cobalt-based alloys are favored for high-performance applications. The base element, typically nickel or cobalt, is the single greatest element in the superalloy by weight. Illustrative nickel-base superalloys include at least about 40% Ni, and at least one component from the group consisting of cobalt, chromium, aluminum, tungsten, molybdenum, titanium, and iron. Examples of nickel-base superalloys are designated by the trade names Inconel®, Nimonic®, Rene®, (e.g., Rene80®, Rene 95®, Renel42®, and Rene N5® alloys), and Udimet®, and include directionally solidified and single crystal superalloys. Illustrative cobalt-based superalloys include at least about 30 wt % Co, and at least one component from the group consisting of nickel, chromium, aluminum, tungsten, molybdenum, titanium, and iron. Examples of cobalt-base superalloys are designated by the trade names Haynes®, Nozzaloy®, Stellite® and Ultimet®.

Shown in FIG. 5 on the surface blade 110 at the concave side of the airfoil 114 are discrete local surface areas 116 and 118 that are subject to more strenuous thermal conditions during service operation of the blade 110 in a turbine. In some unique patterns, such areas 16 and 18 merge along the leading edge of the airfoil 114. This type of thermal pattern results in non-uniform degradation at such an article surface, including non-uniform diffusion of a surface coating such as an aluminide coating into the article base metal, and/or oxidation of an exposed aluminide coating. In the above described type of TBC system, the article surface areas, for example on an airfoil surface, subjected to the highest temperatures experience greater diffusion loss of critical aluminide coating elements into the base metal, and the potential for TBC spallation and subsequent exposure of aluminide coating to the oxidizing and corrosive atmosphere. Cooler locations on the surface of components with such a TBC system may virtually be unaffected by engine operation. Airfoil coatings degrade with time at high operating temperatures due to such factors as hot corrosion, oxidation, dirt accumulation, thermal cycle fatigue, etc. Consequently, the airfoil must be periodically repaired which includes removing the degraded coatings, mechanically repairing the airfoil, and then re-coating the airfoil surface.

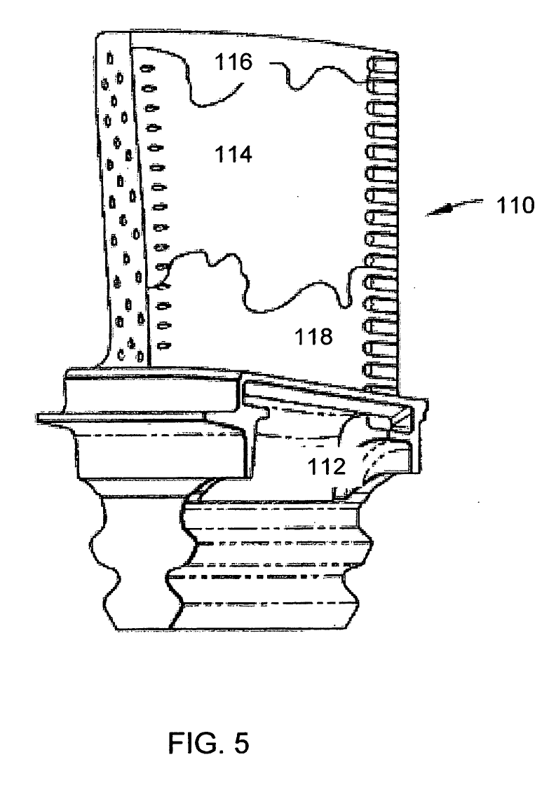

As depicted in FIGS. 6A, 6B and 6C, the repair of the turbine airfoils often involves one or more cleaning and stripping steps to remove foreign deposits, thermally grown oxides (TGO's), and degraded engine-TBC systems. In one common repair scheme, acid solutions are pumped through airfoil internals to remove the aluminide coating down to the base metal (FIG. 6B). Once the airfoil coating(s) is removed and weld/braze repairs are completed, the typical final repair step includes the application of a new coating(s). Unfortunately, current chemical cleaning and stripping solutions can attack the base metal resulting in either a significantly more involved repair process or an airfoil rendered unusable (i.e., scrapped). Both of these issues add considerable cost to the repair process through either additional touch and cycle time or the purchasing of a new airfoil.

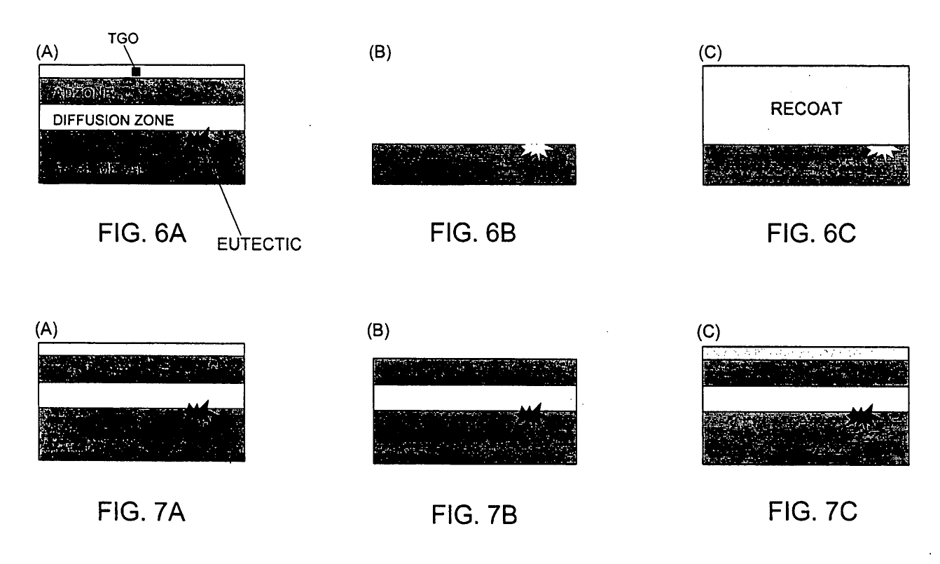

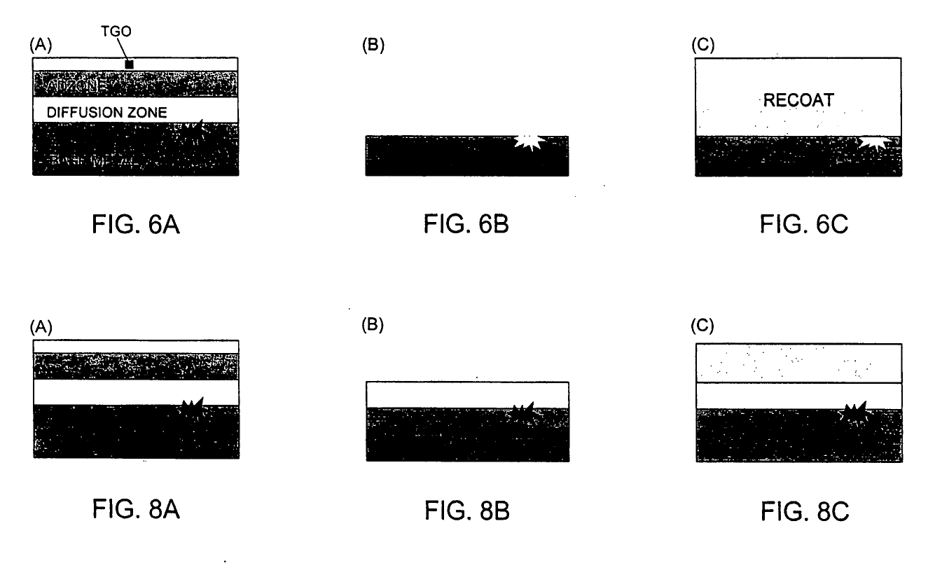

As depicted in FIGS. 7A, 7B and 7C, the repair of the turbine airfoils may be performed to involve only TGO removal followed by re-aluminiding. Such an operation may occur after TBC system removal and/or on the internals of an airfoil. Alternatively as depicted in FIGS. 8A, 8B and 8C, the repair of the turbine airfoils may be performed to involve TGO and partial alumide layer removal. Both processes avoid base metal (eutectic) attack. Also, both processes maintain airfoil wall thicknesses, and in certain instances can reduce the realuminiding time (e.g., slurry aluminiding often requires multiple coats to get desired coating thickness). Both processes are unlike processes that use chemistries that attack the base metal and base metal eutectics create excessive intergranular attack (IGA) resulting in airfoils being discarded

The re-aluminiding process is used to rebuild coating thickness. With superalloys, such as nickel-base and cobalt-base, re-aluminiding process is typically formed by a diffusion process, e.g., using a pack cementation-type procedure, and usually contains aluminum.

The diffusion process generally entails reacting a surface of the treaded base metal with an aluminum-containing gas composition. After heat treatment two distinct sublayers, the outermost of which is referred to as the aluminide layer, and the innermost of which is a diffusion zone. The aluminide layer contains an environmentally-resistant intermetallic, represented by MAl; where M is iron, nickel or cobalt, depending on the substrate material. The MAI intermetallic is often the result of the diffusion of deposited aluminum into the base metal, and a general, outward diffusion of iron, nickel or cobalt from the base metal. During high temperature exposure in air, the MAI intermetallic forms a protective aluminum oxide (alumina) scale that inhibits oxidation of the coating and the underlying substrate. The chemistry of the aluminide layer can be modified by the presence of additional elements, such as chromium, silicon, platinum, rhodium, hafnium, yttrium and zirconium. As a result of changes in elemental solubility (in the local regions of the substrate and gradient), the diffusion zone is thus formed. Due to reactivity, the diffusion zone contains various intermetallic and metastable phases—products of all alloying elements from the substrate and coating.

Describe hereafter is the process (FIGS. 8A, 8B & 8C) as reduced to practice on a piece of 9FA S2 engine-run airfoil (nozzle). The procedure included,

1) An about 10 hour immersion in an about 5M phosphoric acid in an ultrasonic cleaner at between about 85 and 90° C. to remove TGO and at least a partially the aluminide layer.

2) A hot water rinse.

3) An activated aluminide slurry recoating on partially stripped surfaces which were either as-stripped or vapor honed.

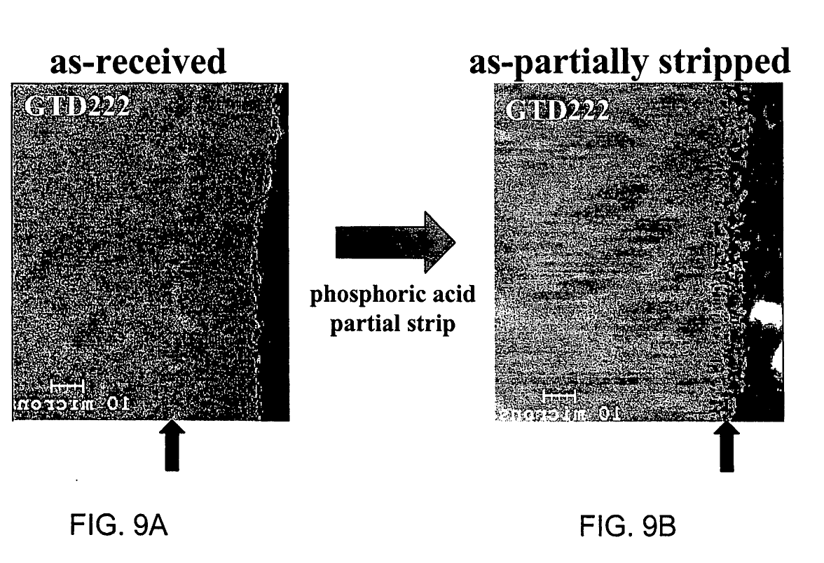

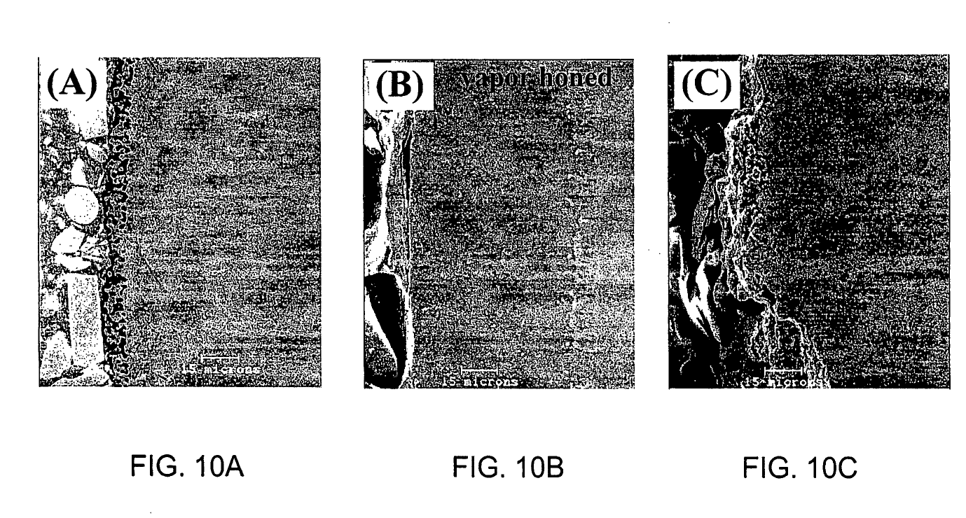

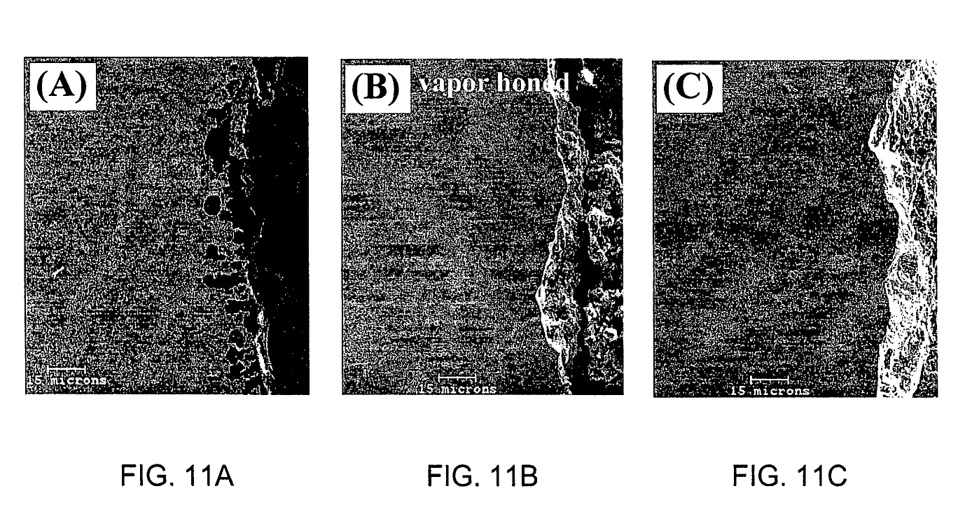

FIG. 9A shows the as-received engine-run aluminide coating from the cooling hole of a 9FA S2 nozzle and FIG. 9A shows the same coating after partial strip with phosphoric acid. At no time was the base metal exposed to the acid solution. FIGS. 10A-11C show the pressure (FIGS. 10A, 10B & 10C), suction, and cooling hole (FIGS. 11A, 11B & 11C) surfaces after re-aluminiding with a slurry process. An activated slurry was prepared by adding 5 5 by weight of AlF3 to a slurry available from a commercial vendor. This slurry was then applied to the parts and dried, after which the parts were diffusion treated at 1,950 F for 2 hours in a flowing argon gas atmosphere. All three surfaces show a coherent chemically bonded aluminide coating. Surfaces which were vapor honed prior to slurry coating appeared to yield more uniform aluminide coatings (FIGS. 10B & 11B) than recoating on as-stripped surfaces (FIGS. 10C & 11C).

The two alternative processes of FIGS. 7A-7C and FIG. 8A-8C provide benefits that include, but are not limited to:

(1) Being applicable to aluminide airfoils (buckets and nozzles);

(2) Substantially no base metal (eutectic) attack;

(3) Elimination of airfoil scrapping due to base metal reduction resulting from chemical stripping;

(4) Maintenance of airfoil wall thicknesses;

(5) Shorter repair cycle with less touch time;

(6) Better quality repair.

(7) As described here, the solutions are environmentally “friendly.”

(8) No full chemical line set up.

While the use of slurry coating was demonstrated, there is no reason that foam coating, pack, and vapor phase aluminiding would not also work. Also, any subsequently developed stripping solutions which also remove just TGO or TGO and aluminide layer would leave the surfaces amenable to coating rejuvenation.

In operation, the airfoil is immersed in a bath containing the transportable environmentally safe compound. Immersion in this manner (in any type of vessel) often permits the greatest degree of contact between the aqueous composition and the coating that is being removed. Immersion time and bath temperature will depend on many of the factors described above, such as the type of coating being removed, and the amount of acid being used in the bath. Usually, the bath is maintained at a temperature in the range of about room temperature to about 100° C., while the substrate is immersed therein. In preferred embodiments, the temperature is maintained in the range of about 30° C. to about 85° C. In some especially preferred embodiments, the temperature range is about 35° C. to about 55° C. The immersion time may vary considerably, but it is usually in the range of about 1 minute to about 10 hours, and preferably, in the range of about 10 minutes to about 4 hours. (Longer immersion times may compensate for lower bath temperatures). Typically, the bath is stirred or agitated during the treatment process.

Alternative techniques may be used to treat the airfoil with the transportable environmentally safe compound composition. For example, the airfoil can be continuously sprayed with the composition, using various types of spray guns, or a single spray gun could be employed. Similarly, a line of guns could be used, and the substrate could pass alongside or through the line of guns (or multiple lines of guns). As still another alternative, the coating removal composition could simply be poured over the airfoil (and continuously recirculated).

As a result of treatment, the airfoil in the stripping bath usually forms a residue referred to as “smut” or “coating residue.” This occurs because the degraded, aluminide layer material continues to weakly adhere to the underlying diffusion sublayer-substrate. Consequently, treatment is usually followed by a post-stripping step, often referred to as a “de-smutting” operation. Such a step is known in the art, and described in various references. It may be in the form of an abrasion step, employed because it minimizes damage to the underlying diffusion zone and the substrate, e.g., grit blasting. For example, a pressurized air stream (usually less than about 100 psi.), containing aluminum oxide particles, can be directed across the surface. The duration of grit blasting in this embodiment will depend on various factors, such as the thickness and specific composition of the smut-layer; the size and type of grit media, and the like. Typically, the process is carried out for about 30 seconds to about 3 minutes.

Other known techniques for abrading the surface may be used in lieu of grit-blasting. Many of these are described in U.S. Pat. No. 5,976,265, incorporated herein by reference. For example, the surface can be manually scrubbed with a fiber pad, e.g. a pad with polymeric, metallic, or ceramic fibers. Alternatively, the surface can be polished with a flexible wheel or belt in which aluminum or silicon carbide particles have been embedded. Liquid abrasive materials may alternatively be used on wheels or belts. These alternative techniques would be controlled in a manner that maintained a contact force against the surface that was no greater than the force used in the grit-blasting technique discussed above.

Other techniques (or combinations of techniques) could be employed in place of abrasion, to remove the degraded material. Examples include tumbling of the article (e.g., water-tumbling), or laser ablation of its surface. Alternatively, the degraded material could be scraped off the surface. As still another alternative, sound waves (e.g., ultrasonic) could be directed against the surface, causing vibrations that can shake loose the degraded material. For each of these alternative techniques, those skilled in the art would be familiar with operating adjustments that are made to control the relevant force applied against the surface of the articles (as in the case of the abrasion technique), to minimize damage to the substrate or coating diffusion zone being preserved. The article is sometimes rinsed after this step, e.g., using water or a combination of water and a wetting agent.

Although the discussion in this application has been focused on airfoils, a variety of other coated substrates may processed using the invention to remove coatings. Applicant contemplate processing substrates that are made from a metallic material, for example, primarily formed of metal or metal alloys, but which may also include some non-metallic components. Non-limiting examples of metallic materials are those which comprise at least one element selected from the group consisting of iron, cobalt, nickel, aluminum, chromium, titanium, and mixtures which include any of the foregoing (e.g., stainless steel).

The actual configuration of a substrate may vary widely. As a general illustration, the substrate may be in the form of a houseware item (e.g., cookware) or a printed circuit board substrate. In many embodiments, superalloy substrates are in the form of turbine engine components, such as combustor liners, combustor domes, shrouds, or airfoils. The present invention is useful for removing coatings from the flat areas of substrates, as well as from curved or irregular surfaces that may include indentations, hollow regions, or holes (e.g., film cooling holes).

As noted above, the method of the present invention may be used in conjunction with a process for repairing protective coatings that are sometimes applied over the coatings described above. As an example, thermal barrier coatings (TBC's) are frequently applied over aluminide coatings to protect turbine components from excessive thermal exposure. The periodic overhaul of the TBC sometimes requires that the underlying aluminide layer and diffusion zone also be removed. The TBC can be removed by various methods, such as grit blasting or chemical techniques. The process described above can then remove the underlying coating or multiple coatings. The component can subsequently be conventionally re-coated with aluminide, followed by standard coating with fresh TBC.

The replacement coating can then be applied to the substrate. Examples of coatings to be applied include the diffusion-aluminide coatings, and overlay coatings. A non-limiting example of an overlay coating is one having a composition of the formula MCrAl(X), where M is an element selected from the group consisting of Ni, Co, Fe, and combinations thereof; and X is an element selected from the group consisting of Y, Ta, Si, Hf, Ti, Zr, B, C, and combinations thereof. Diffusion aluminide coatings can be applied as described previously. The overlay coatings are also applied to the surface by conventional techniques, such as high velocity oxy-fuel (HVOF), plasma spray (e.g., air plasma spray), physical vapor deposition, and the like. Those skilled in the art are aware of other aspects of the coating process, e.g., cleaning and/or surface roughening steps, when appropriate.

As mentioned before, repeated stripping and re-applications of diffusion-aluminide coatings can undesirably alter the thickness of the substrate, e.g., a turbine airfoil. When the partial stripping process of this invention is carried out, the aluminide layer of such a coating can be repeatedly removed and replaced. Thus, the specified wall thickness of the airfoil can be maintained for a greater service period. This advantage is an important feature in a commercial setting, where component replacement and repair is a time-consuming and expensive undertaking.

The above-described process selectively removes the aluminide layer of the diffusion aluminide-coatings. The underlying diffusion zone remains substantially unaffected. Moreover, the process does not attack or deplete the substrate. Once the aluminide layer is removed from the coating, the component may undergo de-smutting and deposition of a new coating.

Certain modifications and improvements will occur to those skilled in the art upon a reading of the foregoing description. It should be understood that all such modifications and improvements have been deleted herein for the sake of conciseness and readability but are properly within the scope of the following claims.

1-50. (canceled)

51. A method for refurbishing an airfoil, the method comprising:
partially removing an aluminide coating from an airfoil using an environmentally safe stripper system while not attacking the base metal of the airfoil.

52. A method for refurbishing an airfoil, the method comprising:
partially removing an aluminide coating from an airfoil using a transportable environmentally safe compound while not attacking the base metal of the airfoil.

53. A method for refurbishing an airfoil, the method comprising:
(a) partially removing an aluminide coating from an airfoil using a transportable environmentally safe compound while not attacking the base metal of the airfoil; and
(b) restoring said aluminide coating to said airfoil having said partially removed an aluminide coating.

54. The method of claim 53 wherein restoring comprises at least one of vapor-phase aluminizing system and pack aluminizing.

55. The method of claim 53 wherein restoring comprises applying a precursor.

56. The method of claim 53, further comprising oxide descaling.

57. The method of claim 53 wherein partially removing and restoring are performed within a single facility.

58. The method of claim 53 wherein the compound comprises at least one of phosphoric acid, acetic acid, and citric acid.

59. The method of claim 53 further comprising applying a mask to the airfoil to selectively protect areas of the airfoil from the compound.

60. The method of claim 52 further comprising applying a mask to the airfoil to selectively protect areas of the airfoil from the compound.
